(19) United States
(12) Patent Application Publication
(10) Pub. No.: US 2014/0001633 A1
(43) Pub. Date: Jan. 2, 2014

(54) COPPER INTERCONNECT STRUCTURE AND METHOD FOR FABRICATING THEREOF

(71) Applicants: Chi-Wen Huang, Taoyuan (TW); Kuo-Hui Su, Taoyuan (TW)

(72) Inventors: Chi-Wen Huang, Taoyuan (TW); Kuo-Hui Su, Taoyuan (TW)

(73) Assignee: NANYA TECHNOLOGY CORPORATION, TAOYUAN (TW)

(21) Appl. No.: 13/535,217

(22) Filed: Jun. 27, 2012

(51) Int. Cl. H01L 23/48; H01L 21/768

(52) U.S. Cl. 257/741; 438/675; 257/E21.586; 257/E23.011

(57) ABSTRACT

A method for fabricating a copper interconnect structure is disclosed. A substrate having a conductive region is provided. An insulating layer with a via opening is formed on the substrate. The via opening exposes the conductive region. A copper layer is formed on the first insulating layer and fills the via opening by sequentially performing deposition and reflowing processes. A masking layer is formed on the copper layer to cover the via opening. The copper layer uncovered by the masking layer is anisotropically oxidized. The masking layer and the oxidized copper layer are removed by a wet etching process, to form a copper plug in the via opening and a copper wire line on the copper plug. A copper interconnect structure is also disclosed.

### BACKGROUND OF THE INVENTION

1. Field of the Invention

The invention relates to semiconductor technology, and in particular to a copper interconnect structure and a method for fabricating thereof.

2. Description of the Related Art

In the fabrication of integrated circuits, the dimensions of semiconductor devices in the integrated circuits (ICs), such as transistors, resistors, capacitors or other semiconductor elements well known in the art, has been continuously reduced in order to increase device density. Typically, interconnect structures are used for electrical connection of the individual semiconductor devices.

The interconnect structure comprises plugs and metal layers, in which aluminum and aluminum alloys are traditional metal interconnect materials. However, since copper has a lower resistivity compared to traditional aluminum or aluminum alloys, it can reduce time constant (RC) delay and power consumption in an IC, wherein R is the resistance and C is the capacitance of the IC. Accordingly, copper is widely applied to the interconnect structures in semiconductor devices.

Such an interconnect structure is typically provided by a dual damascene process. FIGS. 1A to 1E illustrate a conventional method for fabricating a copper interconnect structure using a dual damascene process. Referring to FIG. 1A, a substrate 100, such as a silicon substrate, is provided. The substrate 100 may contain a conductive layer 102 comprising metal, such as copper, commonly used for wiring the discrete semiconductor devices (not shown) in and on the substrate. An insulating layer 104 including an interlayer dielectric (ILD) and/or intermetal dielectric (IMD) layer is formed on the substrate 100. Moreover, a first photoresist layer 106 with a via opening pattern 106a is formed on the insulating layer 104.

Referring to FIG. 1B, a via opening 104a is anisotropically etched through the insulating layer 104 using the first photoresist layer 106 as an etch mask, to expose the conductive layer 102. After removal of the first photoresist layer 106, a second photoresist layer 108 with a trench opening pattern 108a is formed on the insulating layer 104.

Referring to FIG. 1C, a trench opening 104b is also anisotropically etched through the insulating layer 104 using the second photoresist layer 108 as an etch mask, such that the trench opening 104b is above and corresponds to the via opening 104a to form a dual damascene opening. After removal of the second photoresist layer 108, a copper seed layer 110 is conformably formed on the insulating layer 104 and the inner surface of the dual damascene opening (i.e., the trench opening 104b and the via opening 104a).

Referring to FIG. 1D, a copper layer 112 is formed on the insulating layer 104 and fills the dual damascene opening by performing a plating process. Thereafter, the excess copper layer 112 above the dual damascene opening is removed by a chemical mechanical polishing (CMP) process, as shown in FIG. 1E.

However, since the dimension of the interconnect structure is reduced as the dimension of the semiconductor device is reduced, the aspect ratio (AR) of the dual damascene opening is increased. As a result, one or more voids 114 may be formed in the copper layer 112 when the plating process is performed, as shown in FIGS. 1D and 1E. Moreover, impurities (not shown) in the copper layer 112 may be increased due to the plating process. Such undesired defects increase the resistivity and reduce the reliability of the interconnect structure.

Accordingly, there is a need to develop an improved copper interconnect structure and an improved method for fabricating thereof, mitigating or eliminating the aforementioned problem.

### BRIEF SUMMARY OF THE INVENTION

An exemplary embodiment of a method for fabricating a copper interconnect structure comprises providing a substrate having a conductive region. An insulating layer with a via opening is formed on the substrate. The via opening exposes the conductive region. A copper layer is formed on the first insulating layer and fills the via opening by sequentially performing deposition and reflowing processes. A masking layer is formed on the copper layer to cover the via opening. The copper layer uncovered by the masking layer is anisotropically oxidized. The masking layer and the oxidized copper layer are removed by a wet etching process, to form a copper plug in the via opening and a copper wire line on the copper plug.

Another exemplary embodiment of a copper interconnect structure comprises a substrate having a conductive region. A first insulating layer with a via opening is disposed on the substrate, wherein the via opening exposes the conductive region. A copper wire line is disposed on the first insulating layer. A copper plug is extended from the copper wire line into the via opening. A second insulating layer conformably covers the first insulating layer and the copper wire.

### BRIEF DESCRIPTION OF DRAWINGS

The invention can be more fully understood by reading the subsequent detailed description and examples with references made to the accompanying drawings, wherein:

FIGS. 1A to 1E are cross sections of a conventional method for fabricating a copper interconnect structure using a dual damascene process; and

FIGS. 2A to 2F are cross sections of an embodiment of a method for fabricating a copper interconnect structure for a semiconductor device according to the invention.

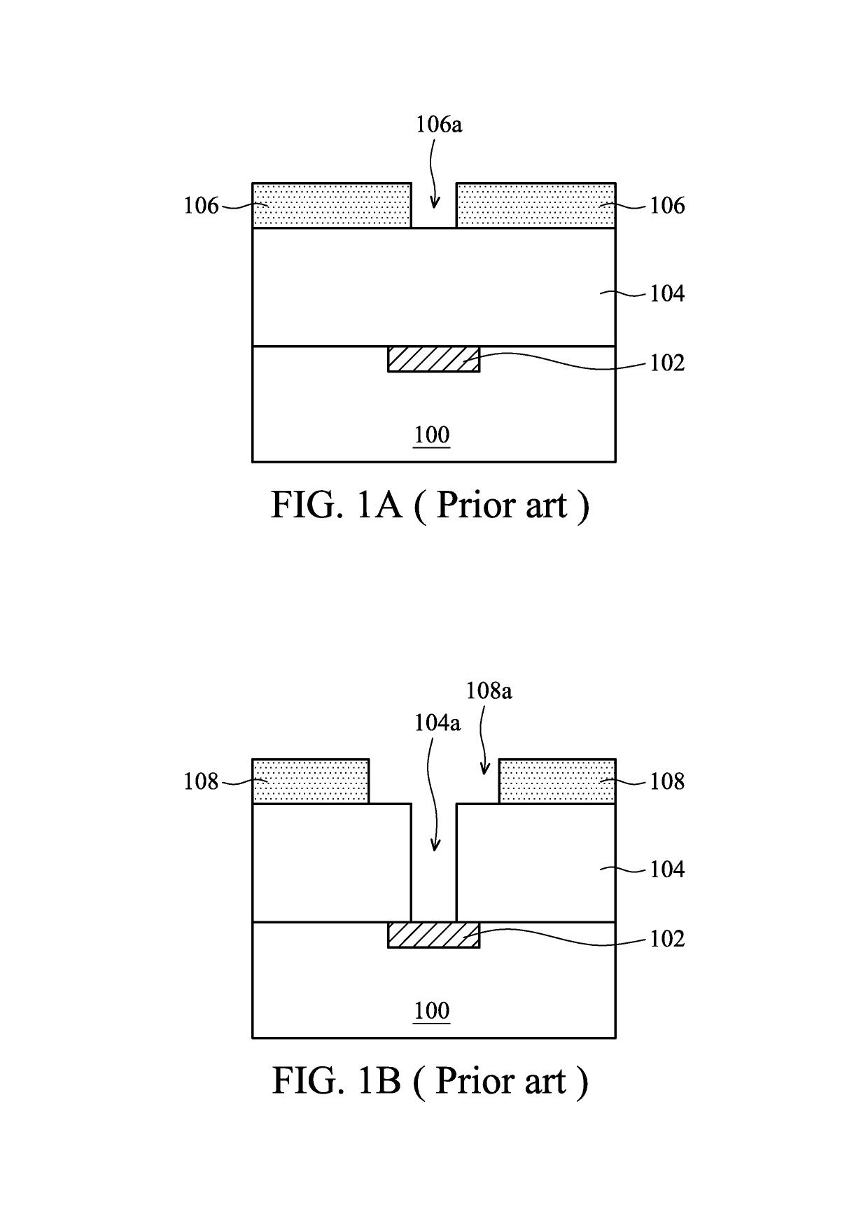

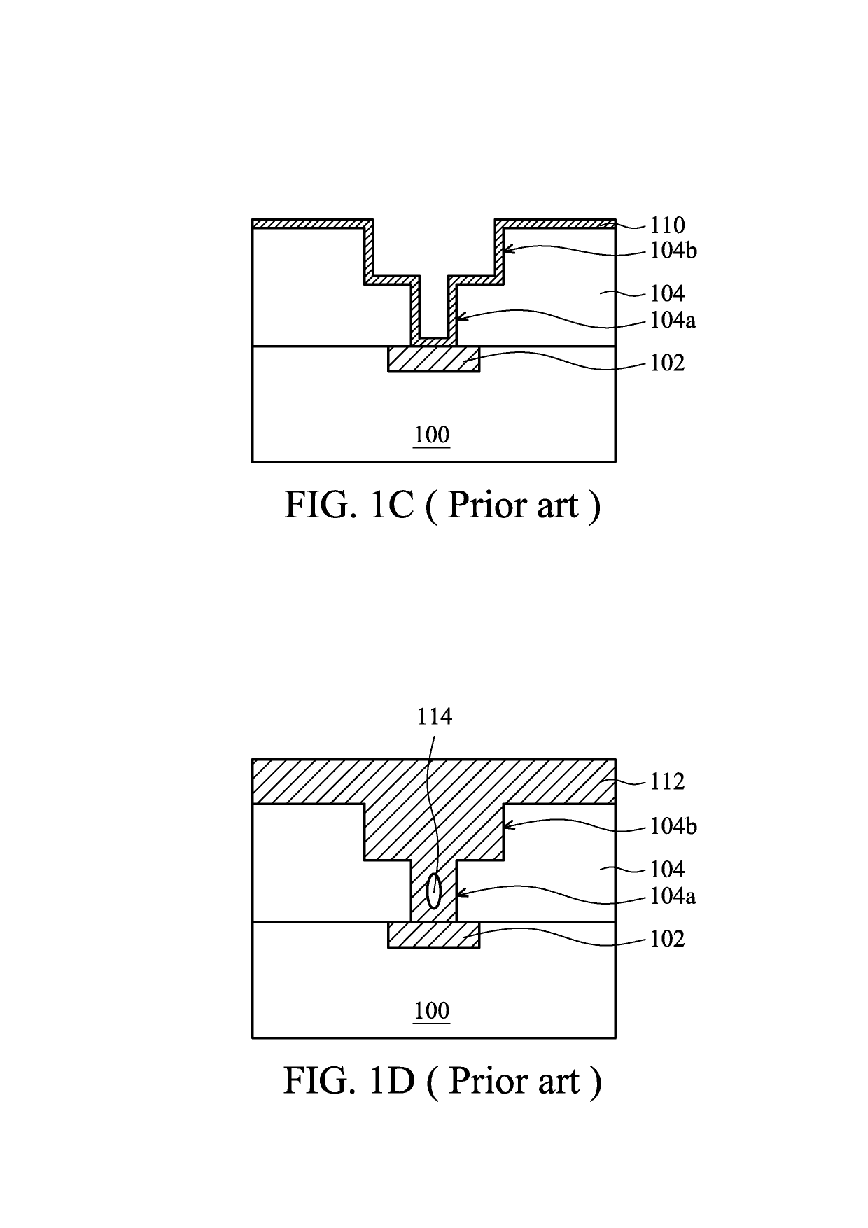

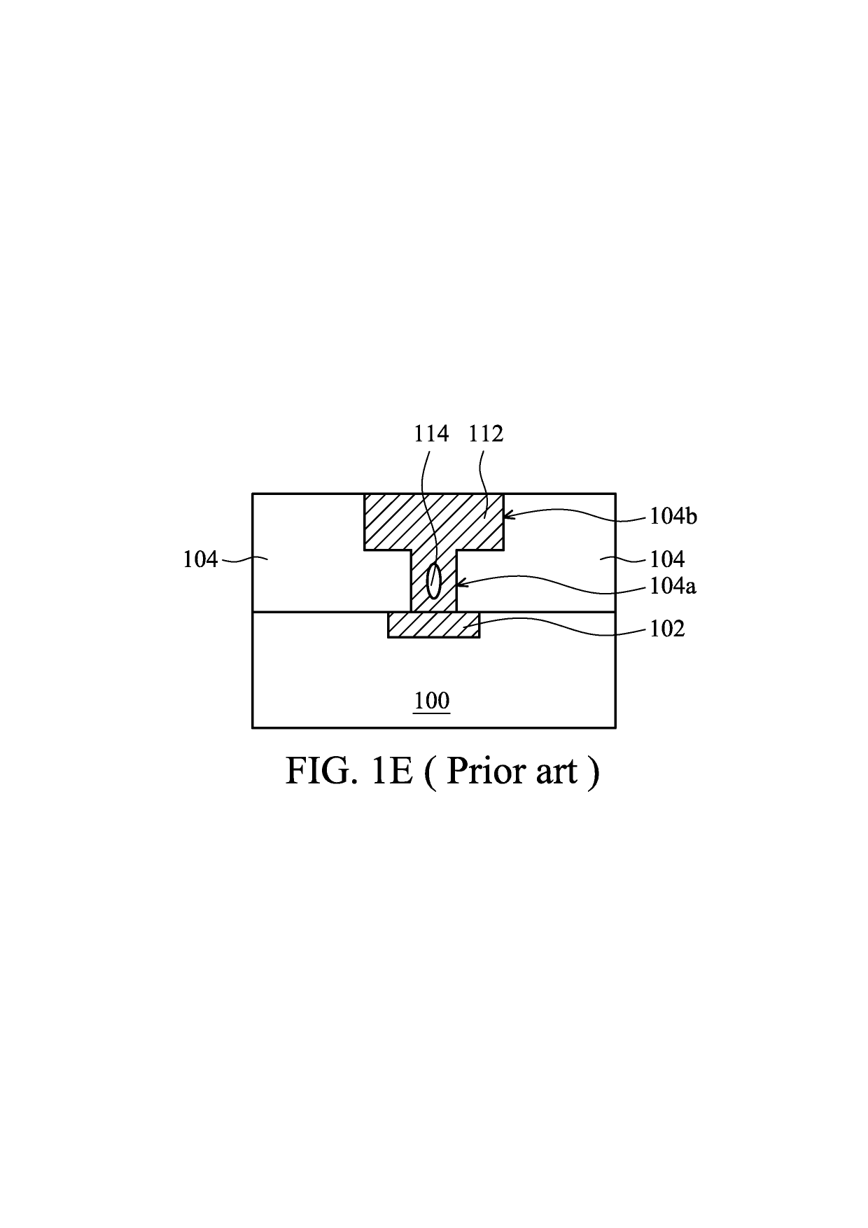

### DETAILED DESCRIPTION OF INVENTION

The following description encompasses the fabrication process and the purpose of the invention. It can be understood that this description is provided for the purpose of illustrating the fabrication process and the use of the invention and should not be taken in a limited sense. In the drawings or disclosure, the same or similar elements are represented or labeled by the same or similar symbols. Moreover, the shapes or thicknesses of the elements shown in the drawings may be magnified for simplicity and convenience. Additionally, the elements not shown or described in the drawings or disclosure are common elements which are well known in the art.

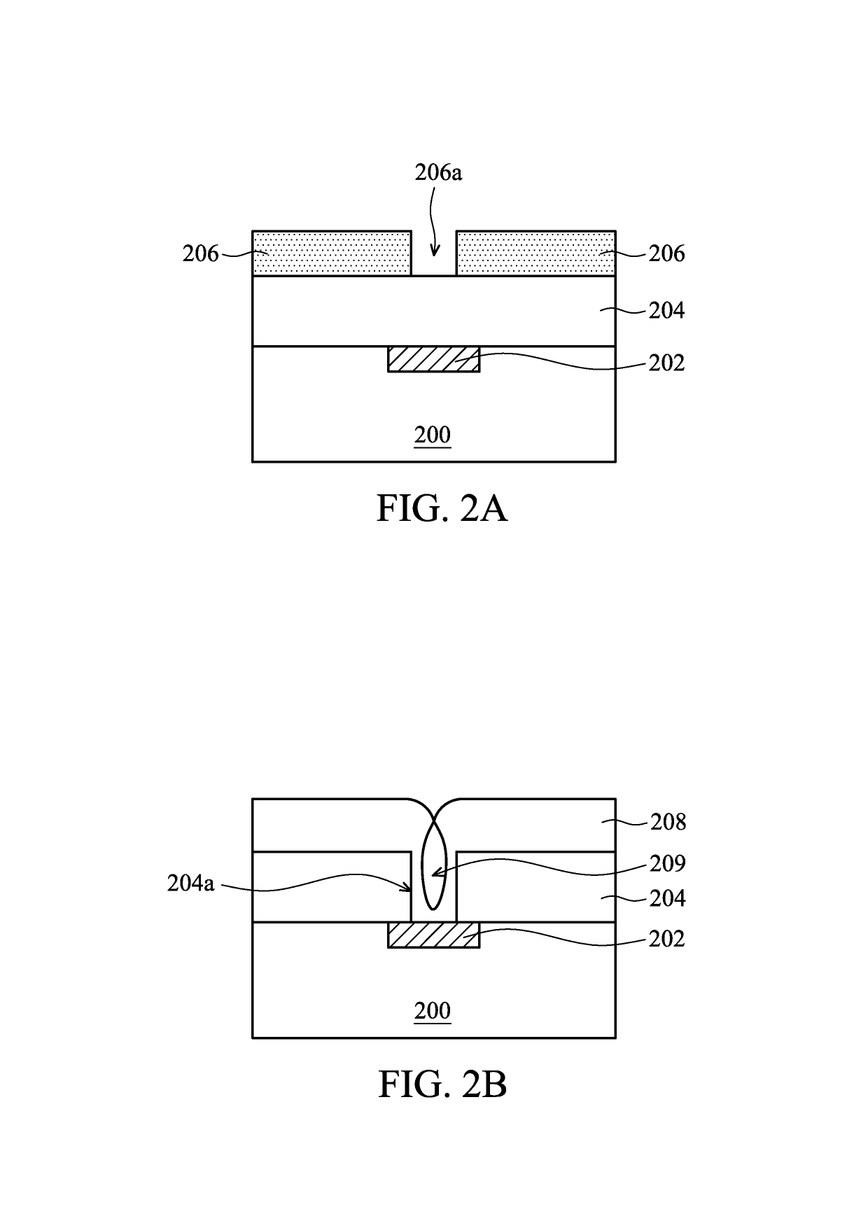

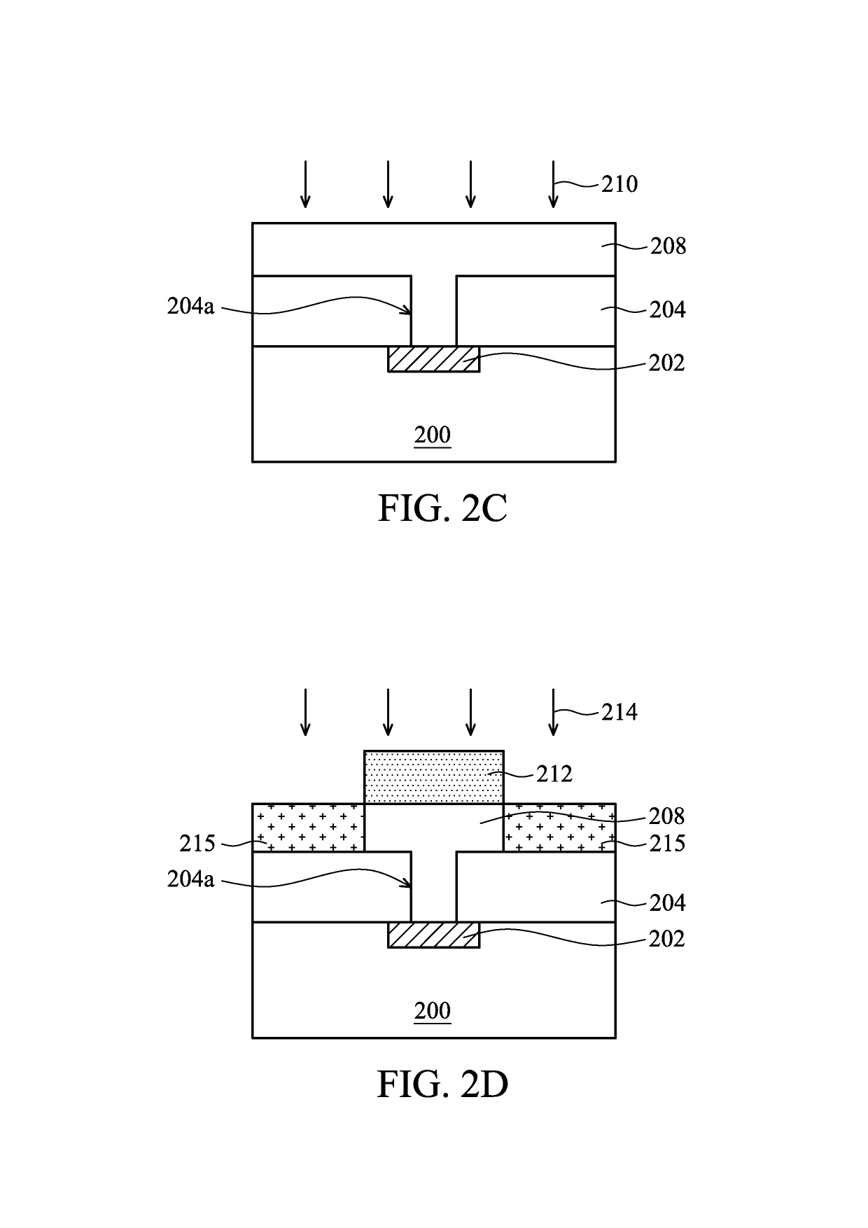

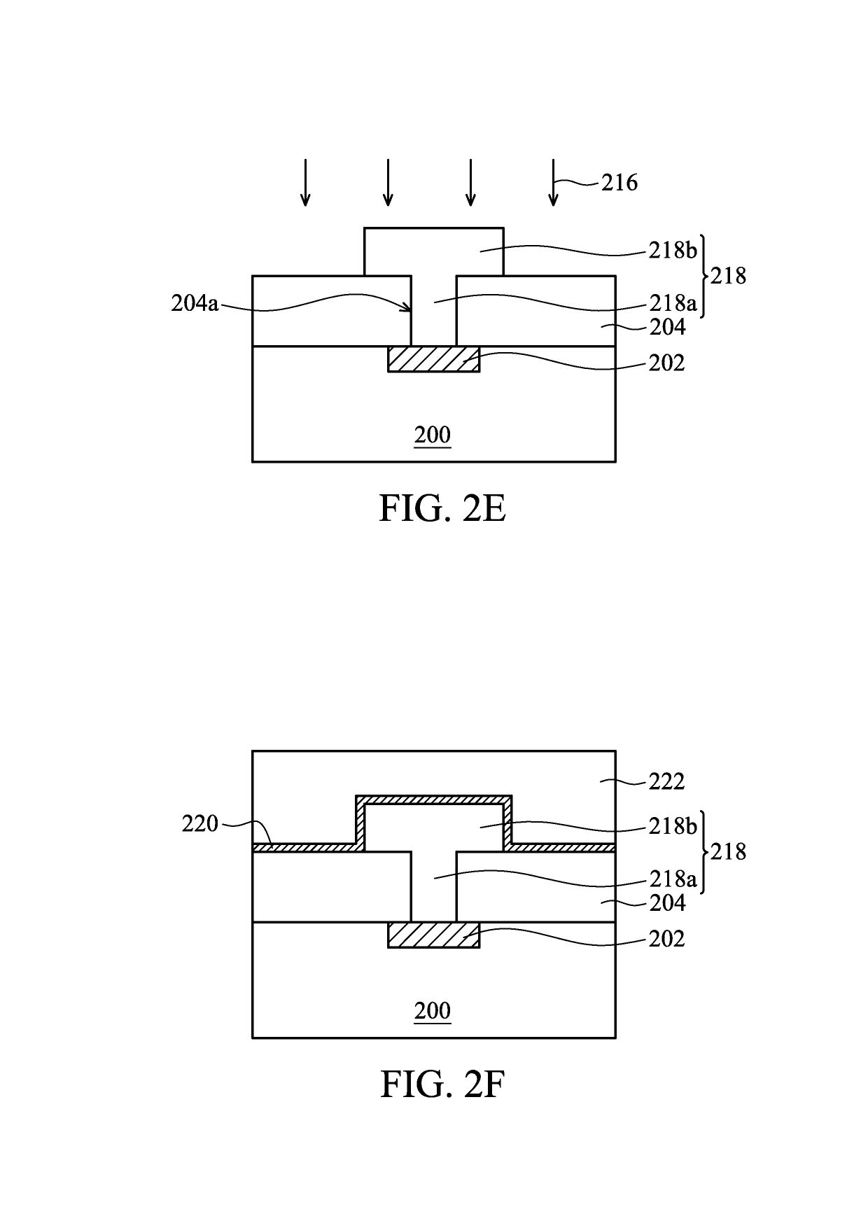

FIG. 2F illustrates a copper interconnect structure for a semiconductor device. The copper interconnect structure comprises a substrate 200, first and second insulting layers 204 and 220 and an interconnect 218. In the embodiment, the substrate 200 may be a silicon substrate or other semiconductor substrates. The substrate 200 may contain various elements (not shown), including transistors, resistors, capacitors, and other semiconductor elements which are well known in the art. Moreover, the substrate 200 may comprise at least one conductive region 202 to electrically connect the elements in the substrate 200 to other elements therein or an external circuit (not shown) through a subsequently formed interconnect, such as a copper interconnect. In one embodiment, the conductive region 202 may be a metal layer, such as copper or aluminum or other wire line materials known in the art. Alternatively, the conductive region 202 may be a doping region, such as an n-type or p-type doping region.

The first insulting layer 204 has at least one via opening 204a therein and is disposed on the substrate 200. The via opening 204a exposes the conductive region 202 of the substrate 200. In one embodiment, the first insulting layer 200 may serve as an interlayer dielectric (ILD) or intermetal dielectric (IMD) layer. Moreover, the first insulating layer may comprise silicon oxide, phosphosilicate glass (PSG), borophosphosilicate glass (BPSG) or low dielectric constant (k) material, such as fluorosilicate glass (FSG) or organosilicate glass (OSG) or a combination thereof.

The interconnect 218 is disposed on the first insulting layer 204 and electrically connected to the conductive region 202 of the substrate 200 through the via opening 204a formed in the first insulating layer 204. In the embodiment, the interconnect 218 includes a copper plug 218a and a copper wire line 218b. The copper wire line 218b is on the first insulating layer 204 and corresponds to the via opening 204a. The copper plug 218a is extended from the copper wire line 218b into the via opening 204a, such that the copper plug 218a and the copper wire line 218b are formed integrally. The interconnect 218 may further include an optional metal barrier layer (not shown), such as Ti, TiN, Ta, TaN or a combination thereof, which is conformably formed on the inner surface of the via opening 204a and between the first insulating layer 204 and the copper wire line 218b.

The second insulating layer 220 conformably covers the first insulting layer 204 and the copper wire line 218b. The second insulating layer 220 may serve as a diffusion barrier layer to prevent the copper atoms in the copper wire line 218b from diffusing. In one embodiment, the second insulating layer 220 may comprise a barrier low K material, such as SiNx, SiCN, SiCOx for preventing Cu migration.

In another embodiment, the copper interconnect structure may further comprise a third insulating layer 222 to cover the copper wire line 218b. For example, the third insulating layer 222 is disposed on the second insulating layer 220 to cover the first insulating layer 204 and the copper wire line 218b. The third insulating layer 222 may be composed of a material similar to or the same as that of the first insulating layer 204.

FIGS. 2A to 2F are cross sections of an embodiment of a method for fabricating a copper interconnect structure for a semiconductor device according to the invention. Referring to FIG. 2A, a substrate 200 is provided. The substrate 200 may be a silicon substrate or other semiconductor substrates. Moreover, the substrate 200 may comprise at least one conductive region 202 to electrically connect the elements (not shown), such as transistors, resistors, capacitors, and other semiconductor elements which are well known in the art, in the substrate 200 to other elements therein or an external circuit (not shown) through a subsequently formed interconnect. In one embodiment, the conductive region 202 may be a metal layer, such as copper or aluminum or other wire line materials known in the art. Alternatively, the conductive region 202 may be a doping region, such as an n-type or p-type doping region.

A first insulating layer 204 serving as an ILD or IMD layer is formed on the substrate 200 by a deposition process, such as plasma enhanced chemical vapor deposition (PECVD), high-density plasma CVD (HDPCVD) or other suitable CVD well known in the art. In one embodiment, the first insulating layer 204 may be a single layer or have a multi-layer structure. Moreover, the first insulating layer 200 may comprise silicon oxide, PSG, BPSG or low dielectric constant (k) material (such as FSG or OSG) or a combination thereof. Next, a masking layer 206, such as a photoresist layer, is formed and patterned on the first insulating layer 204 by a conventional lithography process. The patterned masking layer 204 has at least one opening pattern 206a correspondingly above the conductive region 202 of the substrate 200.

Referring to FIG. 2B, a via opening 204a is formed in the first insulating layer 204 by an etching process using the masking layer 206 (shown in FIG. 2A) as an etch mask, to expose the conductive region 202 of the substrate 200. After the via opening 204a is formed, the masking layer 206 is removed. Thereafter, a copper layer 208 is formed on the first insulating layer 208 and fills the via opening 204a by a suitable deposition process, such as physical vapor deposition (PVD). Optionally, a metal barrier layer (not shown), such as Ti, TiN, Ta, TaN or a combination thereof, is conformably formed on the inner surface of the via opening 204a prior to formation of the copper layer 208. When the size of the semiconductor device is reduced, the aspect ratio of the via opening 204a is high, such that a void 209 may be formed in the copper layer 208.

Accordingly, as shown in FIG. 2C, after the copper layer 208 is formed, a reflow process 210 is subsequently performed on the copper layer 208, such that the copper layer 208 can entirely fill the via opening 204a without forming any voids in the cooper layer 208. In one embodiment, the reflow process 210 is performed at a temperature in a range of about 250° C. to 450° C.

Referring to FIG. 2D, a masking layer 212, such as a photoresist layer, is formed and patterned on the copper layer 208 by a conventional lithography process, thereby covering the via opening 204a and a region of the copper layer 208 where a wire line is to be formed. Next, the copper layer 208 uncovered by the masking layer 212 is anisotropically oxidized. For example, a decoupled plasma oxidation (DPO) process 214 is performed to the copper layer 208 uncovered by the masking layer 212 at a room temperature, to form an oxidized copper layer 215 on the first insulating layer 204. During the DPO process, bias is applied to drive oxygen ions into a specific depth of the copper layer 208 from the surface thereof.

Referring to FIG. 2E, after the oxidized copper layer 215 (shown in FIG. 2D) is formed, the masking layer 212 (shown in FIG. 2D) and the oxidized copper layer 215 are respectively or simultaneously removed by a wet etching process 216, to expose a portion of the first insulating layer 204 and form an interconnect 218 on the first insulting layer 204. The interconnect 218 is electrically connected to the conductive region 202 of the substrate 200 through the via opening 204a of the first insulting layer 204. In the embodiment, the interconnect 218 includes a copper plug 218a and a copper wire line 218b. The copper wire line 218b is on the first insulating layer 204 and corresponds to the via opening 204a. The copper plug 218a is extended from the overlying copper wire line 218b into the via opening 204a.

In one embodiment, the masking layer 212 and the oxidized copper layer 215 may be simultaneously removed using an etching solution comprising acetic acid (CH₃COOH), hydrofluoric acid (HF) and water (H₂O) for the wet etching process 216, wherein the acetic acid is utilized to remove the oxidized copper layer 215 and protect the copper wire line 218b from etching. Moreover, the hydrofluoric acid is utilized to remove the masking layer 212.

In some embodiments, the etching solution may further comprise nitric acid (HNO₃). The nitric acid is utilized to remove the copper residue (not shown) remained on the sidewalls of the copper wire line 218b.

Referring to FIG. 2F, the first insulting layer 204 and the copper wire line 218b are conformably covered by a second insulating layer 220. The second insulating layer 220 may serve as a diffusion barrier layer to prevent the copper atoms in the copper wire line 218b from diffusing. In one embodiment, the second insulating layer 220 may comprise a barrier low K material, such as SiN, SiCN, SiCOx and be formed by the conventional deposition process, such as CVD. As a result, a copper interconnect structure may be completed.

In another embodiment, a third insulating layer 222 may further be formed on the second insulating layer 220 by the conventional deposition process, such as a CVD process, such that the first insulating layer 204 and the copper wire line 218b are covered by the third insulating layer 222. In this embodiment, the third insulating layer 222 may be composed of a material similar to or the same as that of the first insulating layer 204. Moreover, an additional via opening (not shown) may be formed in the third and second insulating layers 222 and 220. Also, an additional interconnect (not shown) may be formed on the third insulating layer 222 and electrically connected to the interconnect 218 through the additional via opening. The additional via opening and interconnect may be formed by a method similar to or the same as that shown in FIGS. 2A to 2E.

According to the foregoing embodiments, since the void formed in the copper layer corresponding to the via opening can be eliminated by performing a reflow process after formation of the copper layer, the reliability of the copper interconnect structure can be increased. Moreover, impurities in the copper interconnect can be reduced or eliminated by forming the copper layer with a non-plating process. Accordingly, the resistivity of the copper interconnect can be reduced, thereby enhancing the electrical characteristic of the copper interconnect.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a copper interconnect structure, comprising:
providing a substrate having a conductive region;
forming a first insulating layer with a via opening on the substrate, wherein the via opening exposes the conductive region;
forming a copper layer on the first insulating layer and filling the via opening by sequentially performing deposition and reflowing processes;
forming a masking layer on the copper layer to cover the via opening;
anisotropically oxidizing the copper layer uncovered by the masking layer; and
removing the masking layer and the oxidized copper layer by a wet etching process, to form a copper plug in the via opening and a copper wire line on the copper plug.

2. The method of claim 1, further comprising;
conformably covering the first insulating layer and the copper wire line with a second insulating layer on; and
forming a third insulating layer on the second insulating layer to cover the first insulating layer and the copper wire line.

3. The method of claim 2, wherein the first and third insulating layers comprise silicon oxide and the second insulating layer comprises a barrier low K dielectric.

4. The method of claim 1, wherein the conductive region comprises a metal layer or a doping region.

5. The method of claim 1, wherein the deposition process comprises a physical vapor deposition process.

6. The method of claim 1, wherein the copper layer is anisotropically oxidized by performing a decoupled plasma oxidation process.

7. The method of claim 1, wherein the wet etching process uses an etching solution comprising acetic acid and hydrofluoric acid.

8. The method of claim 7, wherein the etching solution further comprises nitric acid.

9. A copper interconnect structure, comprising:
a substrate having a conductive region;
a first insulating layer with a via opening disposed on the substrate, wherein the via opening exposes the conductive region;
a copper wire line disposed on the first insulating layer;
a copper plug extended from the copper wire line into the via opening; and
a second insulating layer conformably covering the first insulating layer and the copper wire.

10. The copper interconnect structure of claim 9, further comprising a third insulating layer on the second insulating layer to cover the first insulating layer and the copper wire line.

11. The copper interconnect structure of claim 10, wherein the third insulating layers comprises silicon oxide.

12. The copper interconnect structure of claim 9, wherein the first comprises silicon oxide.

13. The copper interconnect structure of claim 9, wherein the second insulating layer comprises a barrier low K dielectric.

14. The copper interconnect structure of claim 9, wherein the conductive region comprises a metal layer or a doping region.
